(19) United States
(12) Patent Application Publication
(10) Pub. No.: US 2010/0214066 A1
(43) Pub. Date: Aug. 26, 2010

(54) Chip and Transmitter for Wireless Communication System

(76) Inventor: Meng-Hsiang Lai, Hsinchu County (TW)

Correspondence Address: NORTH AMERICA INTELLECTUAL PROPERTY CORPORATION, P.O. BOX 506, MERRIFIELD, VA, 22116, US

(21) Appl. No.: 12/497,527

(22) Filed: Jul. 2, 2009

(30) Foreign Application Priority Data
Feb. 23, 2009 (TW) 098105619

(51) Int. Cl. H04Q 5/22; H01L 23/48

(52) U.S. Cl. 340/10.1; 257/690; 257/E23.01

(57) ABSTRACT

A chip for a wireless communication system includes a package, a die area formed inside the package for arranging an operating circuit, a pad formed in the die area for outputting a signal, a first pin formed on the package for outputting the signal, a first conductive wire electrically connected between the pad and the first pin, a second pin formed on the package, a capacitor electrically connected between the second pin and a ground end, and a second conductive wire electrically connected between the pad and the second pin.

### BACKGROUND OF THE INVENTION

1. Field of the Invention

The present invention relates to a chip and transmitter for a wireless communication system, and more particularly, to a chip and transmitter for reducing layout area and enhancing filtering effect by utilizing conductive wires to replace inductors.

2. Description of the Prior Art

With advancements in semiconductor and communication technologies, a communication system can be realized by a single chip for reducing a volume of a communication device. However, there are various factors should be considered when designing a single-chip communication system; for example, how to integrate the whole function in a chip with a reasonable volume. Besides, a wireless communication system involves operations of wireless transmission and reception. Hence, related administrations and standards have made proper restrictions (e.g. maximum transmission power, bandwidth, etc.) on different wireless communication systems, to avoid mutual interference or affect human body.

For example, in a wireless local area network (WLAN), a super heterodyne structure is widely used as a wireless transceiver system, which can simply execute carrier frequency adjustment, filtering, and amplifying. However, in a super heterodyne transmitter, an output signal comprises a local oscillator signal and an imaging signal thereof due to operations of a mixer. Under such circumstances, in order to avoid interfering other transceivers, related standards have been made to filter out the local oscillator signal and the imaging signal, and a well-known method is performed by a notch filter.

Please refer to FIG. 1, which is a schematic diagram of a chip 10 in the prior art. The chip 10 is utilized for realizing a super heterodyne transmitter, and a related operating circuit is arranged in a die area 100. Signals received from or transmitted to outside (e.g. antenna, signal source, etc.) is via pads PI_1˜PI_m on the die area 100 and externally connected pins PO_1˜PO_n with conductive wires, e.g. gold wires, connected. For example, if the pad PI_1 and the pin PO_1 are utilized for outputting a radio-frequency signal V_RF, the radio-frequency signal V_RF generated by the die area 100 is transmitted through a conductive wire GW to the pin PO_1 via the pad PI_1, to output the radio-frequency signal V_RF. Besides, as shown in FIG. 1, an output path of the pin PO_1 connects to a notch filter 102, which is utilized for eliminating the local oscillator signal to avoid interfering other transceivers. The notch filter 102 is composed of an inductor L and a capacitor C, which can form a notch-shaped frequency response near a frequency fLO of the local oscillator signal as shown in FIG. 2, in order to eliminate the local oscillator signal.

Via the notch filter 102, the super heterodyne transmitter 10 can ensure that the output radio-frequency signal V_RF does not affect operations of other transmitters. However, as shown in FIG. 1, the inductor L and the capacitor C are formed outside the chip, and inevitably occupy an area, which does not benefit single chip design.

### SUMMARY OF THE INVENTION

It is therefore a primary objective of the present invention to provide a chip for a wireless communication system.

The present invention discloses a chip for a wireless communication system to realize a transmitter. The chip comprises a package, a die area formed inside the package for arranging an operating circuit, a pad formed in the die area for outputting a signal, a first pin formed on the package for outputting the signal, a first conductive wire electrically connected between the pad and the first pin, a second pin formed on the package, a capacitor electrically connected between the second pin and a ground end, and a second conductive wire electrically connected between the pad and the second pin.

The present invention further discloses transmitter for a wireless communication system, which comprises an antenna and a radio-frequency chip. The radio-frequency chip electrically connected to the antenna, which comprises a package, a die area formed inside the package for arranging an operating circuit of the transmitter, a pad formed in the die area for outputting a radio-frequency signal generated by the transmitter, a first pin formed on the package for outputting the radio-frequency signal, a first conductive wire electrically connected between the pad and the first pin, a second pin formed on the package, a second pin formed on the package, a capacitor electrically connected between the second pin and a ground end, and a second conductive wire electrically connected between the pad and the second pin.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a chip in the prior art.

FIG. 2 is a schematic diagram of a frequency response of a notch filter shown in FIG. 1.

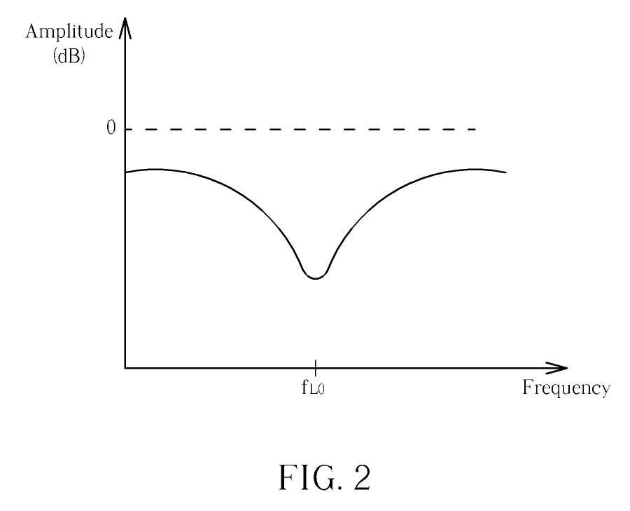

FIG. 3 is a schematic diagram of a chip for a wireless communication system according to an embodiment of the present invention.

FIG. 4 is a schematic diagram of a frequency response generated by a combination of a conductive wire and a capacitor shown in FIG. 3.

### DETAILED DESCRIPTION

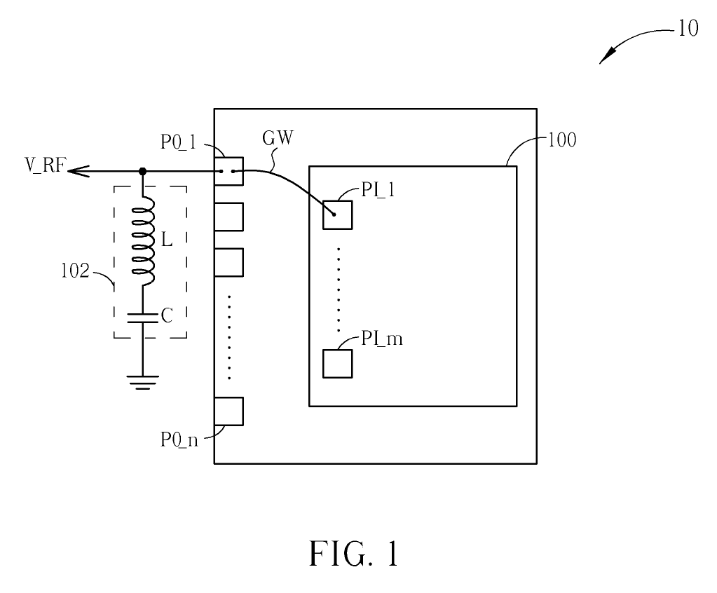

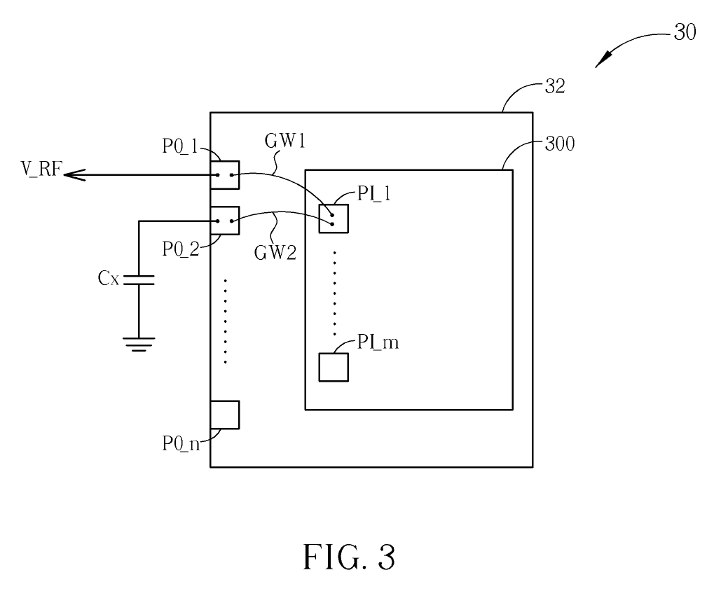

Please refer to FIG. 3, which is a schematic diagram of a chip 30 for a wireless communication system according to an embodiment of the present invention. The chip 30 is utilized for realizing a transmitter or a transceiver, and is preferably a super heterodyne transmitter. The chip 30 comprises a package 32, a die area 300, pads PI_1˜PI_m, and pins PO_1˜PO_n. A structure and an operation of the chip 30 are similar to those of the chip 10 shown in FIG. 1, while the present invention reduces the inductor L, to save a layout area and production cost, and detailed description is as follows.

In the chip 30, the pad PI_1 and the pin PO_1 are utilized for outputting a radio-frequency signal V_RF. After the die area 300 generates the radio-frequency signal V_RF, the radio-frequency signal V_RF is transmitted to the pin PO_1 via a conductive wire GW1, to output the radio-frequency signal V_RF to an antenna (not shown in FIG. 3 for simplicity). Besides, as shown in FIG. 3, the pad PI_1 electrically connects to the pin PO_2 via a conductive wire GW2, to further connect to an external capacitor Cx. The pin PO_2 is a dummy pin, and the conductive wire GW2 forms an inductor. In other words, a combination of the conductive wire GW2 and the capacitor Cx forms a notch filter.

Simply speaking, the present invention realizes the inductor of the notch filter by the conductive wire GW2, to reduce a capacitor in the chip 30 and reach a goal of saving the layout area and production cost. Note that, the chip 30 shown in FIG. 3 is to illustrate the concept of the present invention, and those skilled in the art can make modifications and alterations accordingly. For example, positions, shapes and sizes of the pad PI_1 and the pins PO_1, PO_2 can be varied in response to different systems, and should not be limited. Besides, a length of the conductive wire GW2 affects the generated inductance, such that the capacitor Cx is preferably a variable capacitor, especially a capacitor with capacitance capable of being externally adjusted, for matching the conductive wire GW2, to generate a correct stop band.

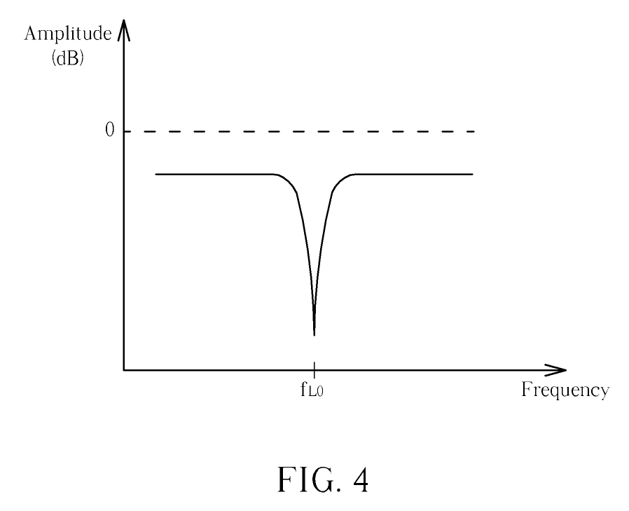

In addition, a material of the conductive wire GW2 is usually a metal with high conductivity, e.g. gold, and with better Q value. In other words, when the conductive wire GW2 is combined with the capacitor Cx, a more ideal frequency response can be generated as shown in FIG. 4.

In FIG. 3, the chip 30 is utilized for realizing the transmitter, and replaced the inductor of the notch filter with the conductive wire GW2. Certainly, other applications requiring connecting inductors to signal transmission paths can take the same action. Besides, layout, packaging methods, etc. can be varied according to different requirements. For example, the chip 30 can apply Quad Flat No Lead (QFN) package, Flip-Chip package, Ball Grid Array (BGA) package, etc.

In the prior art, to avoid interfering other transceivers, the notch filter is required to filter out the local oscillator signal from the radio-frequency signal outputted from the transmitter. Under such circumstances, the capacitor and the inductor of the notch filter inevitably occupy an area, which does not benefit single chip design. In comparison, the present invention replaces the inductor with the conductive wire, to reduce the required area. Meanwhile, since the Q value of the conductive wire is higher than the inductor, the present invention can further increase the effect of stop band, to enhance the operation of filtering.

To sum up, for the transmitter of the single chip, the present invention replaces the inductor with the conductive wire, to reduce the required area and enhance the effect of filtering.

Those skilled in the art will readily observe that numerous modifications and alterations of the device and method may be made while retaining the teachings of the invention.

What is claimed is:

1. A chip for a wireless communication system comprising:
a package;
a die area inside the package, for arranging a circuit;
a pad, formed in the die area, for outputting a signal;
a first pin, formed on the package, for outputting the signal;
a first conductive wire, electrically connected between the pad and the first pin;
a second pin, formed on the package;
a capacitor, electrically connected between the second pin and a ground end; and
a second conductive wire, electrically connected between the pad and the second pin.

2. The chip of claim 1, wherein the second pin is a dummy pin.

3. The chip of claim 1, wherein the second conductive wire forms an inductor.

4. The chip of claim 1, wherein a combination of the second conductive wire and the capacitor forms a notch filter.

5. The chip of claim 1, wherein the capacitor is a variable capacitor.

6. The chip of claim 1, wherein the capacitance of the capacitor can be adjusted externally.

7. A transmitter for a wireless communication system comprising:
an antenna; and
a radio-frequency chip, electrically connected to the antenna, the radio-frequency chip
comprising:
a package;
a die area, formed inside the package, for arranging an operating circuit of the transmitter;
a pad, formed in the die area, for outputting a radio-frequency signal generated by the transmitter;
a first pin, formed on the package, for outputting the radio-frequency signal;
a first conductive wire, electrically connected between the pad and the first pin;
a second pin, formed on the package;
a capacitor, electrically connected between the second pin and a ground end; and
a second conductive wire, electrically connected between the pad and the second pin.

8. The transmitter of claim 7, wherein the second pin is a dummy pin.

9. The chip of claim 7, wherein the second conductive wire forms an inductor.

10. The chip of claim 7, wherein a combination of the second conductive wire and the capacitor forms a notch filter.

11. The chip of claim 7, wherein the capacitor is a variable capacitor.

12. The chip of claim 7, wherein the capacitance of the capacitor can be adjusted externally.

13. The chip of claim 7, wherein the transmitter is a super heterodyne transmitter.
